(19) United States
(12) Patent Application Publication
(10) Pub. No.: US 2022/0320812 A1
(43) Pub. Date: Oct. 6, 2022

(54) Cooling Device

(71) Applicant: Nippon Telegraph and Telephone Corporation, Tokyo (JP)

(72) Inventors: Shin Toyota, Tokyo (JP); Sohan Kawamura, Tokyo (JP)

(21) Appl. No.: 17/640,028

(22) PCT Filed: Sep. 5, 2019
(86) PCT No.: PCT/JP2019/034957

§ 371 Date: Mar. 3, 2022

(51) Int. Cl. H01S 3/04; H01L 23/427

(52) U.S. Cl. CPC H01S 3/0407; H01L 23/427; H01S 3/0401

(57) ABSTRACT

A cooling jacket that houses a cooling fluid is provided. The cooling jacket includes a fixing part to which an element to be cooled is fixed. Furthermore, an inflow port through which the cooling fluid flows into the cooling jacket and an outflow port through which the cooling fluid flows out of the cooling jacket are provided. Furthermore, a bar-shaped (columnar) member is provided as a mechanism that enhances heat conduction between the cooling fluid in the cooling jacket and the fixing part via a heat transfer member.

This patent application is a national phase filing under section 371 of PCT application no. PCT/JP2019/034957, filed on Sep. 5, 2019, which application is hereby incorporated herein by reference.

### TECHNICAL FIELD

The present invention relates to a cooling device that cools a light diffraction element or the like.

### BACKGROUND

A light diffraction element typified by a Fresnel lens is an optical component that converts a pattern of light intensity by using the nature of light as a wave, which is used in various industrial fields. For example, a Fresnel lens collects light having a certain wavelength by using periodicity at the wavelength pitch. Typically, a Fresnel lens is one obtained by thinning a thick lens. Currently, in addition to the Fresnel lens having the function of collecting light, there have been developed and used many other diffraction elements that convert a form of a light beam in various ways by utilizing wave engineering.

As described in Non-Patent Literature 1, one of the applications of this technology is a large power laser, which has been used in optics for laser resonator and optics for laser beam transmission. Typical continuous output high power lasers are gas dynamic lasers and chemical lasers, both of which are characterized in that the oscillation wavelength is in the infrared region and has a long wavelength. Thus, they have been developed as heat ray lasers, the mirror material of which is a metallic reflector. In the infrared region, a high reflectance mirror such as one having a dielectric multilayer film cannot be obtained and accordingly 2% absorption is present. For example, in the case of a laser device with a megawatt-class output, a 20-k heat input is constantly present at 2% absorption, and the problem of thermal breakdown becomes worse.

To avoid heat deformation of the light diffraction element as much as possible and to prevent the thermal breakdown, cooling with a cooling mechanism is necessary in addition to considering the material of the optical substrate. As an example, there is a technology of causing air containing water droplets to collide with the back of the laser mirror to perform cooling with vaporization heat of the water droplets.

### CITATION LIST

### Non-Patent Literature

Non-Patent Literature 1: Kenichi UEDA, “Adaptive Optics for High Power Lasers,” The Review of Laser Engineering, Volume 27, Issue 2, Pages 84 to 88, 1999.

### SUMMARY

### Technical Problem

As described above, in the application of the high power laser, it is necessary to use a cooling mechanism. However, to perform effective cooling, a heat dissipation radiator that cools the laser mirror as a heat source needs to be increased in size, for example, resulting in a large-scale cooling mechanism and limiting the usage pattern.

Embodiments of the present invention have been made to solve the problems as described above, and an object thereof is to provide a downsized cooling device that more effectively cools a diffraction element used in a high power laser, or the like.

### Means for Solving the Problem

A cooling device according to embodiments of the present invention includes a cooling jacket including a fixing part to which an element to be cooled is fixed; an inflow port through which a cooling fluid flows into the cooling jacket; an outflow port through which the cooling fluid flows out of the cooling jacket; a heat transfer member disposed in contact with the element fixed to the fixing part, so as to be capable of contacting the cooling fluid in the cooling jacket, for conducting heat between the cooling fluid in the cooling jacket and the fixing part; and a mechanism that enhances heat conduction between the cooling fluid in the cooling jacket and the fixing part via the heat transfer member.

### Effects of Embodiments of the Invention

As described above, according to embodiments of the present invention, there is provided the mechanism that enhances heat conduction between the cooling fluid in the cooling jacket and the fixing part via the heat transfer member, so that it is possible to provide a downsized cooling device that more effectively cools a diffraction element used in a high power laser, or the like.

### BRIEF DESCRIPTION OF THE DRAWINGS

FIG. 1A is a cross-sectional view illustrating a configuration of a cooling device according to Embodiment 1 of the present invention.

FIG. 1B is a cross-sectional view illustrating a configuration of the cooling device according to Embodiment 1 of the present invention.

FIG. 1C is a cross-sectional view illustrating a partial configuration of the cooling device according to Embodiment 1 of the present invention.

FIG. 2A is a cross-sectional view illustrating a configuration of a cooling device according to Embodiment 2 of the present invention.

FIG. 2B is a cross-sectional view illustrating a configuration of the cooling device according to Embodiment 2 of the present invention.

FIG. 3 is a cross-sectional view illustrating a configuration of a cooling device according to Embodiment 3 of the present invention.

FIG. 4A is a cross-sectional view illustrating a configuration of a cooling device according to Embodiment 4 of the present invention.

FIG. 4B is a cross-sectional view illustrating a configuration of the cooling device according to Embodiment 4 of the present invention.

FIG. 5A is a cross-sectional view illustrating a configuration of a cooling device according to Embodiment 5 of the present invention.

FIG. 5B is a cross-sectional view illustrating a configuration of the cooling device according to Embodiment 5 of the present invention.

FIG. 6 is a cross-sectional view illustrating a configuration of a cooling device according to Embodiment 6 of the present invention.

### DETAILED DESCRIPTION OF ILLUSTRATIVE EMBODIMENTS

Hereinafter, a cooling device according to embodiments of the present invention will be described.

### Embodiment 1

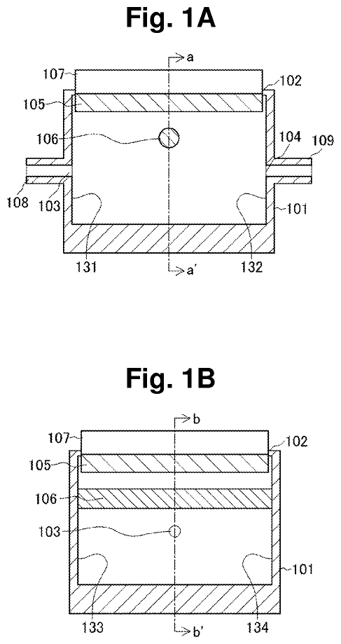

First, a cooling device according to Embodiment 1 of the present invention will be described with reference to FIGS. 1A and 1B. Note that FIG. 1B is a cross section taken along line a-a′ of FIG. 1A. Furthermore, FIG. 1A is a cross section taken along line b-b′ of FIG. 1B.

This cooling device includes a cooling jacket 101 that houses a cooling fluid. The cooling jacket 101 includes a fixing part 102 to which an element 107 to be cooled is fixed. The element 107 is, for example, a diffraction element.

The cooling jacket 101 is a jig including the fixing part 102 that fixes the element 107 and is not limited in shape, material, placement angle in the cooling device, size, length, and weight. In addition, there is no limitation on the fixing method and the like in the fixing part 102. As an example, the cooling jacket 101 has a rectangular shape and includes a mechanism which fixes the element 107 so as to interpose the element 107 between certain faces (fixing part 102). The cooling jacket 101 internally includes a path for circulating the cooling fluid to be capable of cooling the element 107 fixed to the fixing part 102. The cooling jacket 101 may be sized to match the size of the element 107 and thus can be downsized.

Furthermore, this cooling device includes an inflow port 103 through which the cooling fluid flows into the cooling jacket 101, and an outflow port 104 through which the cooling fluid flows out of the cooling jacket 101. The inflow port 103 is provided in a first face perpendicular to the face of the fixing part 102 of the cooling jacket 101, and the outflow port 104 is provided in a second face perpendicular to the face of the fixing part 102 of the cooling jacket 101, which is different from the first face. Note that in the present embodiment, an inflow joint pipe 108 is connected to the inflow port 103, and an outflow joint pipe 109 is connected to the outflow port 104.

The inflow joint pipe 108 and the outflow joint pipe 109 are not limited in shape, material, angle, size, and the like. For example, in the case where each of the inflow joint pipe 108 and the outflow joint pipe 109 is used while being connected to a hose having an inner diameter r, the shape of each of the inflow joint pipe 108 and the outflow joint pipe 109 can have a length allowing attachment of a fastener for fixing the hose and have a columnar shape whose outer diameter is r.

Furthermore, the inflow port 103 and the outflow port 104 can be different in opening shape, size, and the like. For example, the inner diameters of the inflow port 103 and the outflow port 104 can be different in size. For example, when the outflow port 104 has a larger inner diameter than the inflow port 103, conduit resistance in the outflow port 104 can be reduced. Even in the case where the cooling fluid is liquid, a decrease in the outflow rate can be prevented without increasing the inflow rate. That is, the cooling fluid circulates more easily.

The inflow joint pipe 108 and the outflow joint pipe 109 can also be different in shape, material, angle, size, and the like. For example, when the inner diameter of the inflow port 103 is made larger than the inner diameter of the inflow joint pipe 108, conduit resistance in the inflow can be reduced and the inflow rate can be increased. Furthermore, the pipe diameter of the inflow joint pipe 108 can be different in dimension from the diameter of the inflow port 103. Similarly, the pipe diameter of the outflow joint pipe 109 can be different in dimension from the diameter of the outflow port 104.

Furthermore, to increase the outflow rate, the shape of the inlet of the outflow port 104 can be a curved face 104a (FIG. 1C). In the case of an inflow from a wide region into the outflow joint pipe 109, a loss occurs in the outflow port 104 serving as the inlet of the outflow joint pipe 109. To reduce this loss, it is desirable that the cross-sectional shape of the outflow port 104 serving as the inlet of the outflow joint pipe 109 is not squared but is formed so that the pipe diameter expands gradually such that the cross-sectional shape draws a curved face.

On the other hand, the inflow port 103 desirably has a shape that increases the loss, in order to prevent a backflow. To increase the loss, a structure can be provided in which the inflow port 103 serving as the outlet of the inflow joint pipe 108 includes a portion 103a protruding to the inner side of the boundary face.

The cooling fluid is a refrigerant supplied by external equipment such as a chiller, not illustrated, and is formed of any one or more of a liquid, a gas, and a solid. The cooling fluid passes through the circulation path from the external equipment, flows from the inflow port 103 into the cooling jacket 101 via the inflow joint pipe 108, flows out of the outflow port 104, passes through the circulation path via the outflow joint pipe 109 and then circulates to the external equipment.

Furthermore, this cooling device includes a heat transfer member 105 disposed in contact with the element 107 fixed to the fixing part 102, so as to be capable of contacting the cooling fluid in the cooling jacket 101, for conducting heat between the cooling fluid in the cooling jacket 101 and the fixing part 102.

The heat transfer member 105 is in contact with the element 107 and the cooling fluid to transfer heat from the element 107 to the cooling fluid in the interior of the cooling jacket 101. The heat transfer member 105 and the element 107 may be integrated or separated. The heat transfer member 105 is not limited in shape, material, angle, size, weight, and the like, but is desirably formed of a material having a higher melting point and a higher heat conductivity. Furthermore, it desirably has a larger area of a portion in contact with the element 107 and the cooling fluid. For example, the heat transfer member 105 can be provided by coating the back of the element 107 with a material having a higher melting point and a higher heat conductivity (for example, SiC), so that heat from the element 107 can be transferred to the cooling fluid effectively.

In addition, the cooling device according to Embodiment 1 includes a bar-shaped (columnar) member 106 as a mechanism that enhances heat conduction between the cooling fluid in the cooling jacket 101 and the fixing part 102 via the heat transfer member 105. The member 106 extends in the direction perpendicular to the flowing direction of the cooling fluid in the interior of the cooling jacket 101 and is parallel to the face of the fixing part 102. Here, in Embodiment 1, the first face in which the inflow port 103 is provided is a face 131, and the second face in which the outflow port 104 is provided is a face 132, which are disposed to face each other. Furthermore, the member 106 is disposed between a face 133 and a face 134. The face 133 and the face 134 are faces perpendicular to the face of the fixing part 102 and face each other. Furthermore, the face 133 and the face 134 are adjacent to the face 131 and the face 132, respectively.

The member 106 is a fluid obstruction part (turbulent flow generation mechanism) serving as an obstruction to the flow of the cooling fluid and is a portion that generates a turbulent flow. The member 106 is not limited in shape, material, angle, size, weight, arrangement, and the like. As described above, the columnar member 106 is disposed in the vicinity of the heat transfer member 105 in the interior of the cooling jacket 101. In the interior of the cooling jacket 101, the cooling fluid flows along the heat transfer member 105 from the face of the heat transfer member 105 to a face facing it or from the facing face to the face of the heat transfer member 105. The member 106 is disposed in a form of blocking this flow, so that the cooling fluid that has passed through the member 106 generates a turbulent flow. This turbulent flow enhances the heat transfer rate, so that the heat transfer member 105 in the vicinity of the member 106 is cooled and the element 107 can be cooled more effectively.

Different from heat conduction, which is a phenomenon in which heat energy moves in a solid, heat transfer caused by the cooling fluid is a phenomenon in which energy is transported by the movement of an object having heat energy. It is represented by “Q=h(T_{w}−T_{f}) A Δt,” where the movement amount of the energy from the heat transfer caused by the cooling fluid is Q (W), the temperature of the wall (heat transfer member 105) is T_{w}(K), the temperature of the cooling fluid is T_{f} (K), the heat transfer area is A (m²), the elapsed time is Δt, and the heat transfer rate is h (W/m²*K).

The heat transfer rate h is affected not only by the physical property values of the cooling fluid but also by the flow intensity, the mode, and the like. In the case where the flow is a turbulent flow, a fine vortex is generated in the flow. Thus, fluid masses adjacent to each other through this vortex are vigorously stirred or mixed, improving the heat transfer caused by the cooling fluid. The magnitude of the turbulent flow (here, the magnitude of the turbulence of the flow due to the turbulent flow) is expressed by the magnitude of the Reynolds number. If a flow different from the global flow occurs, that is, if a speed difference is present in the fluid, the flow becomes turbulent, and if the turbulence increases, a turbulent flow is generated.

### Embodiment 2

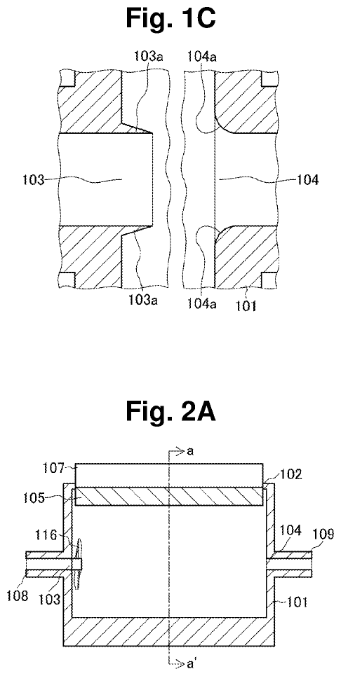

Next, a cooling device according to Embodiment 2 of the present invention will be described with reference to FIGS. 2A and 2B. Note that FIG. 2B is a cross section taken along line a-a′ of FIG. 2A. Furthermore, FIG. 2A is a cross section taken along line b-b′ of FIG. 2B. This cooling device includes the cooling jacket 101, the inflow port 103, the outflow port 104, and the heat transfer member 105. These configurations are the same as those of Embodiment 1 described above, and the cooling jacket 101 includes the fixing part 102 to which the element 107 to be cooled is fixed. Furthermore, the inflow joint pipe 108 is connected to the inflow port 103, and the outflow joint pipe 109 is connected to the outflow port 104.

In addition, the cooling device according to Embodiment 2 includes a rotary vane (stirrer) 116 as a mechanism that enhances heat conduction between the cooling fluid in the cooling jacket 101 and the fixing part 102 via the heat transfer member 105. The rotary vane 116 is disposed in the vicinity of the inflow port 103, for example. The rotary vane 116 is a fluid obstruction part which is movable. The rotary vane 116 can cause a rotational motion in the cooling fluid that has flowed into the cooling jacket 101 through the inflow port 103. The rotational motion caused by the rotary vane 116 stirs the cooling fluid, increasing the heat transfer efficiency in the heat transfer member 105. Furthermore, the rotational direction of the rotary vane 116 is changed in a short time by automatic control, and thereby the cooling fluid is stirred more strongly, increasing the heat transfer efficiency.

### Embodiment 3

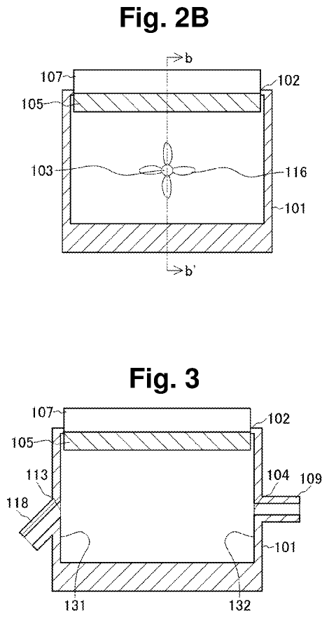

Next, a cooling device according to Embodiment 3 of the present invention will be described with reference to FIG. 3. This cooling device includes the cooling jacket 101, an inflow port 113, the outflow port 104, and the heat transfer member 105. The cooling jacket 101 includes the fixing part 102 to which the element 107 to be cooled is fixed, the same as Embodiment 1 described above. Furthermore, an inflow joint pipe 118 is connected to the inflow port 113, and the outflow joint pipe 109 is connected to the outflow port 104.

Here, the cooling device according to Embodiment 3 includes the inflow joint pipe 118 as a mechanism that enhances heat conduction between the cooling fluid in the cooling jacket 101 and the fixing part 102 via the heat transfer member 105. The pipe axis direction of the inflow joint pipe 118 is in the direction of the heat transfer member 105.

According to Embodiment 3, since the pipe axis direction of the inflow joint pipe 118 is in the direction of the heat transfer member 105, the flow of the cooling fluid flowing in from the inflow port 113 is brought into a state of directly hitting the surface of the heat transfer member 105. Thus, for example, the cooling fluid being cooled can be brought into a state of contacting the heat transfer member 105 while keeping a decreased temperature. This can further increase the temperature difference between the cooling fluid and the heat transfer member 105, as well as the heat flow rate.

Furthermore, according to Embodiment 3, the cooling fluid flows in from the inflow port 113 diagonally with respect to the normal direction of the face 131, so that a turbulent flow can be generated in the interior of the cooling jacket 101. To generate a turbulent flow, it is important to cause a speed difference in the flow. As the flow of the cooling fluid in the interior of the cooling jacket 101 is closer to the wall face, its flow speed is slower due to the friction resistance, and as it is farther from the wall, its flow speed is faster. In this state, at a location near the wall face, the cooling fluid having a high flow speed constantly flows in from the inflow port 113, so that a speed difference occurs, generating a turbulent flow.

According to Embodiment 3, the pipe axis direction of the inflow joint pipe 118 is in the direction of the heat transfer member 105 of a face adjacent to the face 131 in which the inflow port 113 is provided. With this configuration, in the cooling jacket 101, speed vectors in a plurality of directions are caused in the flow of the cooling fluid, and speed differences can be generated in the directions. As a result, a larger turbulent flow can be generated in the cooling fluid in the cooling jacket 101.

### Embodiment 4

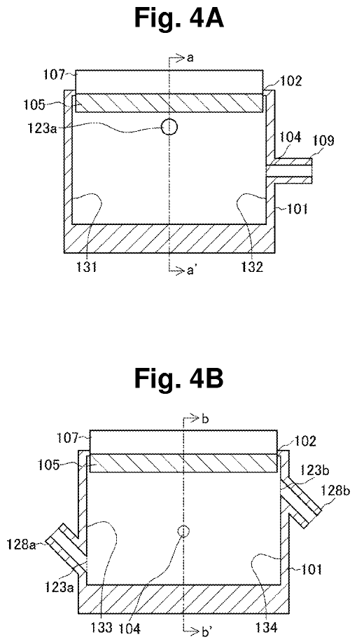

Next, a cooling device according to Embodiment 4 of the present invention will be described with reference to FIGS. 4A and 4B. Note that FIG. 4B is a cross section taken along line a-a′ of FIG. 4A. Furthermore, FIG. 4A is a cross section taken along line b-b′ of FIG. 4B. This cooling device includes the cooling jacket 101, the inflow port 103, the outflow port 104, and the heat transfer member 105. These configurations are the same as those of Embodiment 1 described above, and the cooling jacket 101 includes the fixing part 102 to which the element 107 to be cooled is fixed.

In Embodiment 4, two inflow ports, an inflow port 123a and an inflow port 123b, are provided. One inflow port 123a is provided in the face (first face) 133 perpendicular to the face 132 of the cooling jacket 101 in which the outflow port 104 is provided, and the other inflow port 123b is provided in the face (third face) 134 facing the face 133.

Furthermore, the pipe axis direction of an inflow joint pipe 128a connected to the inflow port 123a is in the direction of the face of the cooling jacket 101 facing the heat transfer member 105, and the pipe axis direction of an inflow joint pipe 128b connected to the inflow port 123b is in the direction in which the heat transfer member 105 is disposed. A plurality of inflow locations is thus provided to increase the source of generation of the turbulent flow, so that the generated turbulent flow can be larger. Furthermore, according to Embodiment 4, the direction of the inflow from the inflow port 123a and the direction of the inflow from the inflow port 123b are on a circle centered on substantially the center in the cooling jacket 101, so that a rotational motion can be caused in the cooling fluid in the cooling jacket 101.

For example, in the case where the cross-sectional area of a face parallel to the face 132 is smaller than the cross-sectional area of a face parallel to the plane of the heat transfer member 105, the flow speed of the cooling fluid due to the rotational motion is faster when the rotational motion is caused in the face parallel to the face 132, according to the law of the conservation of angular momentum. As the flow speed of the cooling fluid increases, the heat transfer rate increases, and thus according to Embodiment 4, the heat flow rate between the cooling fluid and the heat transfer member 105 can be further increased.

### Embodiment 5

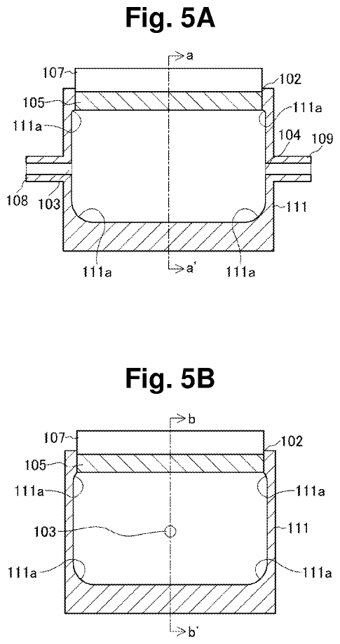

Next, a cooling device according to Embodiment 5 of the present invention will be described with reference to FIGS. 5A and 5B. Note that FIG. 5B is a cross section taken along line a-a′ of FIG. 5A. Furthermore, FIG. 5A is a cross section taken along line b-b′ of FIG. 5B. This cooling device includes a cooling jacket 111, the inflow port 103, the outflow port 104, and the heat transfer member 105. The cooling jacket 111 includes the fixing part 102 to which the element 107 to be cooled is fixed. Furthermore, the inflow joint pipe 108 is connected to the inflow port 103, and the outflow joint pipe 109 is connected to the outflow port 104. The configurations other than the cooling jacket 111 are the same as those of Embodiment 1 described above.

In Embodiment 5, corners 111a of the interior of the cooling jacket 11 are rounded as a mechanism that enhances heat conduction between the cooling fluid in the cooling jacket 111 and the fixing part 102 via the heat transfer member 105. In other words, the cross-sectional shape of the interior of the cooling jacket 111 is substantially elliptical. The corners 111a of the interior of the cooling jacket ill are thus rounded, so that the pipe cross-section through which the cooling fluid flows from the inflow port 103 to the outflow port 104 changes gradually, and the flow of the cooling fluid in each of the inflow port 103 and the outflow port 104 also changes gradually. This reduces the energy loss of the cooling fluid and increases the flow speed of the cooling fluid of the cooling jacket 11, easily mixing the cooling fluid. As a result, in the interior of the cooling jacket 11, the movement of the cooling fluid increases and the heat flow rate also increases.

### Embodiment 6

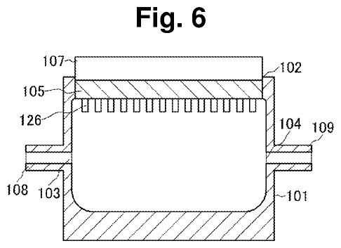

Next, a cooling device according to Embodiment 6 of the present invention will be described with reference to FIG. 6. This cooling device includes the cooling jacket 101, the inflow port 103, the outflow port 104, and the heat transfer member 105. These configurations are the same as those of Embodiment 1 described above, and the cooling jacket 101 includes the fixing part 102 to which the element 107 to be cooled is fixed. Furthermore, the inflow joint pipe 108 is connected to the inflow port 103, and the outflow joint pipe 109 is connected to the outflow port 104.

In addition, in the cooling device according to Embodiment 6, on a face of the heat transfer member 105 facing the inside of the cooling jacket 101, a plurality of fins 126 is provided as a mechanism that enhances heat conduction between the cooling fluid in the cooling jacket 101 and the fixing part 102 via the heat transfer member 105. The fins 126 are, for example, pillar-shaped structures. The fins 126 can be formed of, for example, the same material as the heat transfer member 105. Providing the plurality of fins 126 increases an area where the heat transfer member 105 contacts the cooling fluid, and a larger heat dissipation effect can be obtained.

For example, the material of the heat transfer member 105 is SiC, the thickness of the heat transfer member 105 is 1 mm, the cooling fluid is water, and the heat transfer area between the heat transfer member 105 and the cooling fluid is 100 cm². The heat conductivity of SiC is 200 (W/mK), and the heat transfer rate of the flowing water is about 300 to 10000 (W/m²K). The heat flow rate Q′ (W) between a first object and a second object is represented by Q′=T₁−T₂/R, where the temperature of the first object is T₁ (K), the temperature of the second object is T₂ (K), and the total of the heat resistance is R (K/W). Furthermore, the heat resistance is, in a solid, represented by R=L/kA, where the thickness is L (m) and the heat conductivity is k (W/m*K). Between a solid and a fluid, it is represented by R=1/kA. Thus, in the cooling performance of the cooling device according to the embodiment, the heat resistance between the cooling fluid and the heat transfer member 105 is more dominant than the heat resistance of the heat transfer member 105.

Accordingly, reducing the heat resistance between the cooling fluid and the heat transfer member 105, that is, increasing the contacting area between these, increases the transfer efficiency between the cooling fluid and the heat transfer member 105. The heat resistance of the heat transfer member 105 is 0.05 (K/W) and the heat resistance between the cooling fluid (water) and the heat transfer member 105 is 5 (K/W), where the heat transfer rate of the flowing water is 2000 (W/m²*K). The heat flow rate (W) is represented by the temperature difference divided by the heat resistance, and accordingly where the temperature difference is 100 (K), the heat flow rate is about 20 W.

When the area between the cooling fluid and the heat transfer member 105 is increased 40-fold by providing the plurality of fins 126, the heat resistance between the cooling fluid and the heat transfer member 105 is 1/40, so that the heat flow rate can be further increased, which is about 570 W.

As described above, according to embodiments of the present invention, there are provided the bar-shaped member which extends in the direction perpendicular to the flowing direction of the cooling fluid in the interior of the cooling jacket and which is parallel to the face of the fixing part, the joint pipe which is connected to the inflow port and whose pipe axis direction is in the direction of the heat transfer member, two inflow ports, the cooling jacket with rounded interior corners, the stirrer provided in the interior of the cooling jacket, the mechanism that enhances heat conduction between the cooling fluid in the cooling jacket and the fixing part via the heat transfer member, such as the fins provided on the face of the heat transfer member facing the inside of the cooling jacket, so that it is possible to provide a downsized cooling device that more effectively cools a diffraction element used in a high power laser, or the like.

Note that the present invention is not limited to the embodiments described above, and, of course, many modifications and combinations can be made by those skilled in the art, within the technical concept of the present invention. It is also possible to combine any of the bar-shaped member, the joint pipe whose pipe axis direction is in the direction of the heat transfer member, two inflow ports, the cooling jacket with rounded interior corners, the stirrer provided in the interior of the cooling jacket, and the fins provided on the face of the heat transfer member facing the inside of the cooling jacket.

### REFERENCE SIGNS LIST

101 Cooling jacket
102 Fixing part
103 Inflow port
103a Portion
104 Outflow port
104a Curved face
105 Heat transfer member
106 Member
107 Element
108 Inflow joint pipe
109 Outflow joint pipe
111 Cooling jacket
113 Inflow port
116 Rotary vane (stirrer)
118 Inflow joint pipe
123a Inflow port
123b Inflow port
126 Fin
128a Inflow joint pipe
128b Inflow joint pipe
131 Face
132 Face
133 Face
134 Face

1-8. (canceled)

9. A cooling device comprising:
a cooling jacket comprising a fixing part, wherein the fixing part is configured to hold an element to be cooled;
an inflow port configured to allow a cooling fluid to flow into the cooling jacket;
an outflow port configured to allow the cooling fluid to flow out of the cooling jacket;
a heat transfer member configured to:
contact the element to be cooled and the cooling fluid in the cooling jacket; and
conduct heat between the cooling fluid in the cooling jacket and the fixing part; and
a heat conduction member configured to enhance heat conduction between the cooling fluid in the cooling jacket and the fixing part via the heat transfer member.

10. The cooling device according to claim 9, wherein:
the inflow port is in a first face perpendicular to a face of the fixing part of the cooling jacket;
the outflow port is in a second face perpendicular to the face of the fixing part of the cooling jacket, the second face being different from the first face; and
the heat conduction member extends in a direction perpendicular to a flowing direction of the cooling fluid in an interior of the cooling jacket.

11. The cooling device according to claim 10, wherein the heat conduction member comprises a bar-shaped member disposed parallel to the face of the fixing part.

12. The cooling device according to claim 9, wherein the heat conduction member comprises a joint pipe connected to the inflow port, wherein a pipe axis direction of the joint pipe is in a direction of the heat transfer member.

13. The cooling device according to claim 12, wherein the outflow port is provided in a first face of the cooling jacket and the inflow port is provided in a second face perpendicular to the first face of the cooling jacket.

14. The cooling device according to claim 13, wherein:
the inflow port is provided in the second face perpendicular to the first face of the cooling jacket;
a second inflow port is provided in a third face facing the second face;
a pipe axis direction of a first joint pipe connected to the inflow port is in a direction of a face of the cooling jacket facing the heat transfer member; and
a pipe axis direction of a second joint pipe connected to the second inflow port is in a direction in which the heat transfer member is disposed.

15. The cooling device according to claim 9, wherein the heat conduction member comprises the cooling jacket with a rounded interior corner.

16. The cooling device according to claim 9, wherein the heat conduction member comprises a stirrer provided in an interior of the cooling jacket.

17. The cooling device according to claim 9, wherein the heat conduction member comprises a fin provided on a face of the heat transfer member facing an inside of the cooling jacket.

18. A method of operating a cooling device, the method comprising:
fixing an element to be cooled to a fixing part of a cooling jacket; and
flowing a cooling fluid in the cooling jacket, wherein the cooling fluid flows into the cooling jacket through an inflow port and out of the cooling jacket through an outflow port;
wherein, as the cooling fluid flows through the cooling jacket, the cooling fluid is in contact with a heat transfer member contacting the element to be cooled; and
wherein a heat conduction member enhances heat conduction between the cooling fluid in the cooling jacket and the fixing part via the heat transfer member.

19. The method according to claim 18, wherein:
the inflow port is in a first face perpendicular to a face of the fixing part of the cooling jacket;
the outflow port is in a second face perpendicular to the face of the fixing part of the cooling jacket, the second face being different from the first face; and
the heat conduction member extends in a direction perpendicular to a flowing direction of the cooling fluid in an interior of the cooling jacket.

20. The method according to claim 19, wherein the heat conduction member comprises a bar-shaped member disposed parallel to the face of the fixing part.

21. The method according to claim 18, wherein the heat conduction member comprises a joint pipe connected to the inflow port, wherein a pipe axis direction of the joint pipe is in a direction of the heat transfer member.

22. The method according to claim 21, wherein the outflow port is provided in a first face of the cooling jacket and the inflow port is provided in a second face perpendicular to the first face of the cooling jacket.

23. The method according to claim 22, wherein:
the inflow port is provided in the second face perpendicular to the first face of the cooling jacket;
a second inflow port is provided in a third face facing the second face;
a pipe axis direction of a first joint pipe connected to the inflow port is in a direction of a face of the cooling jacket facing the heat transfer member; and
a pipe axis direction of a second joint pipe connected to the second inflow port is in a direction in which the heat transfer member is disposed.

24. The method according to claim 18, wherein the heat conduction member comprises the cooling jacket with a rounded interior corner.

25. The method according to claim 18, wherein the heat conduction member comprises a stirrer provided in an interior of the cooling jacket.

26. The method according to claim 18, wherein the heat conduction member comprises a fin provided on a face of the heat transfer member facing an inside of the cooling jacket.
